(19) United States
(12) Patent Application Publication
(10) Pub. No.: US 2019/0326931 A1
(43) Pub. Date: Oct. 24, 2019

(54) LOW-DENSITY PARITY CHECK DECODERS AND METHODS THEREOF

(71) Applicant: AVAGO TECHNOLOGIES GENERAL IP (SINGAPORE) PTE. LTD, Singapore (SG)

(72) Inventors: Keke Liu, Fremont, CA (US); Yang Han, Palo Alto, CA (US); Shaohua Yang, San Jose, CA (US); Bruce Wilson, San Jose, CA (US)

(21) Appl. No.: 15/961,529

(22) Filed: Apr. 24, 2018

(51) Int. Cl. H03M 13/11

(52) U.S. Cl. CPC H03M 13/1148; H03M 13/1131

(57) ABSTRACT

An LDPC decoder includes a first circuit is configured to, for a particular check node, determine whether absolute values of two minimums of the absolute values of incoming variable-to-check messages are close to one another. The LDPC decoder includes a second circuit configured to apply either a first scaling value or a second scaling value to check-to-variable messages for the particular check node depending upon whether the first circuit determines that the absolute values of the two minimums of the incoming variable-to-check messages are close to one another.

### FIELD OF THE DISCLOSURE

Example embodiments are directed toward low-density parity check (LDPC) decoders and methods thereof.

### BACKGROUND

Data storage and/or transmission applications (wired and wireless) often use probabilistic error correction techniques for data that may be corrupted due to long-term storage in a medium and/or due to noisy transmission channels. Some of these techniques employ LDPC encoders at the transmitter side and LDPC decoders at the receiver side, which are intended to enable recovery the originally transmitted and/or stored data.

### BRIEF DESCRIPTION OF THE DRAWINGS

The present disclosure is described in conjunction with the appended figures, which are not necessarily drawn to scale:

FIG. 1 illustrates a system according to at least one example embodiment;

FIG. 2 illustrates an example LDPC code in the form of a parity matrix H and associated Tanner graph for use in the system of FIG. 1;

FIG. 3 illustrates a decoding circuit according to at least one example embodiment;

FIG. 4 illustrates an example method for the decoding circuit in FIG. 3 according to at least one example embodiment;

FIG. 5 illustrates a decoding circuit according to at least one example embodiment;

FIG. 6 illustrates a method for the decoding circuit in FIG. 5 according to at least one example embodiment;

FIG. 7 illustrates a decoding circuit according to at least one example embodiment;

FIG. 8 illustrates first and second phases of updating subsets of variable nodes for the decoding circuit of FIG. 7 according to at least one example embodiment; and

FIG. 9 illustrates a method for switching conditions of the decoding circuit of FIG. 7 and phases of FIG. 8 according to at least one example embodiment.

### DETAILED DESCRIPTION

Example embodiments are directed toward various types of LDPC decoders/methods.

At least one example embodiment relates to lowering the error floor of a fixed point LDPC decoder by applying separate scaling factors to various decoder messages (e.g., variable-to-check (V2C) messages, check-to-variable (C2V) messages, and total log-likelihood ratio (LLR) messages). For example, when the number of violated checks is small, the following scaling is applied only to the messages associated with unsatisfied check nodes (CNs): i) separate scaling β is applied for the incoming variable-to-check messages for the unsatisfied CNs. (β<1, in general); 22) a separate scaling ϕ is applied for the total log-likelihood ratio (LLR) messages for the unsatisfied CNs. (ϕ·β=1, in general); and iii) a separate scaling λ_{c} is applied for the generated check-to-variable messages for the unsatisfied CNs. When the number of violated checks increases significantly from a small number to a large number, all the C2V messages in the entire parity check matrix are reset to 0. Decoding as set forth above may lower the error floor for the fixed point LDPC decoder with relatively small additional hardware cost.

At least one example embodiment relates to a dynamic scaling feature to improve error correction performance of a scaled min-sum LDPC decoder. For a given check node (CN), if the two minimums of the absolute values of incoming variable-to-check messages are close to each other, a separate scaling λ_{c} is applied for the generated check-to-variable messages for this CN.

At least one example embodiment relates to a LDPC decoder that employs a two phase method for decoding irregular LDPC codes. Here, the variable nodes (VNs) are partitioned into different subsets based on their degrees (i.e., column weights). In phase 1, only one subset of variable nodes is updated in each iteration, and other subsets of VNs are frozen. Example embodiments may switch from one subset to another subset if some specific conditions are met. Additionally, different VN update algorithms may be applied in different subsets. In phase 2, all VNs are updated in each iteration.

Various aspects of the example embodiments will be described herein with reference to drawings that are schematic illustrations of idealized configurations. It should be appreciated that while particular circuit configurations and circuit elements are described herein, example embodiments are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of example embodiments. Moreover, it should be understood that some or all elements of one example embodiment may be applied to one or more other example embodiments if desired.

It should also be appreciated that example embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB).

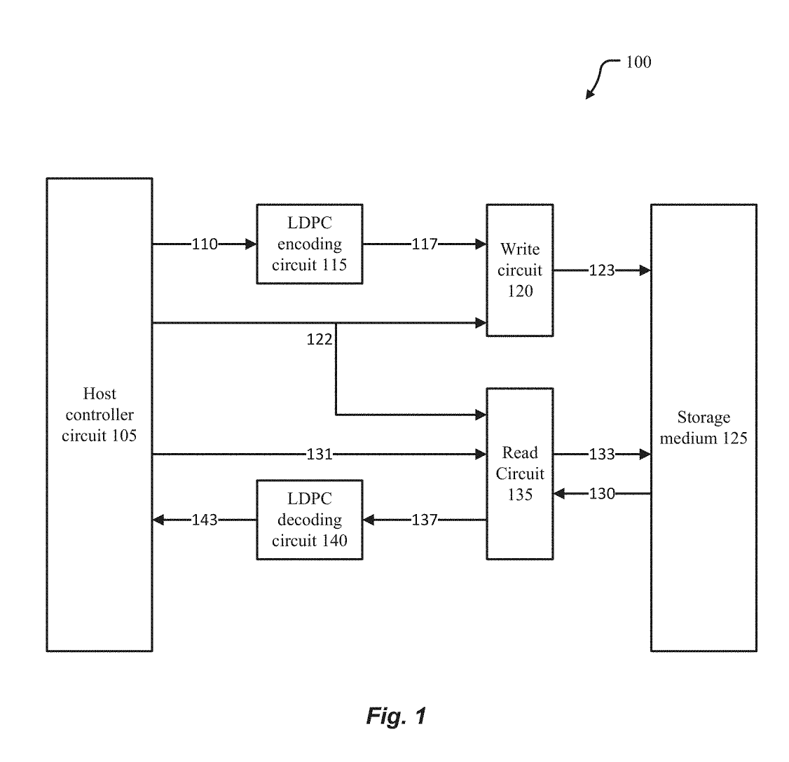

FIG. 1 illustrates a system 100 according to at least one example embodiment. The system 100 may be a storage system that includes a host controller circuit 105, an LDPC encoding circuit (or encoder) 115, a write circuit 120, a storage medium 125, a read circuit 135, and an LDPC decoding circuit (or decoder) 140.

The host controller circuit 105 may control read and/or write operations from/to the storage medium 125. The host controller circuit 105 may be included as part of a host system embodied by hardware and/or software components including but not limited to a computer with a processor or microprocessor or central processing unit (CPU), a mobile phone, a server system, etc.

The LDPC encoding circuit 115 may include hardware and/or software for encoding data 110 according to known LDPC techniques, and outputting encoded data 117 to the write circuit 120. The write circuit 120 may include hardware and/or software for receiving encoded data 117 from the LDPC encoding circuit 115, receiving an address (i.e., a write address) 122 from the host controller circuit 105, and outputting a write signal (e.g., one or more voltage pulses) 123 for writing the data to the storage medium 125 based on the address 122.

The storage medium 125 may include one or more volatile and/or nonvolatile memory devices for storing data, such as solid state disks (SSDs), hard disk drives (HDDs), dynamic random access memory (DRAM), electrically erasable programmable read only memory (EEPROM), etc.

The read circuit 135 may include hardware and/or software for receiving a read request 131 and an associated read address 122 from the host controller circuit 105, applying one or more read voltages 133 to the storage medium 125 based on the address 122, receiving return voltages 130 in response to applying the one or more read voltages 133, and outputting encoded read data 137 (e.g., as binary values) to LDPC decoding circuit 140.

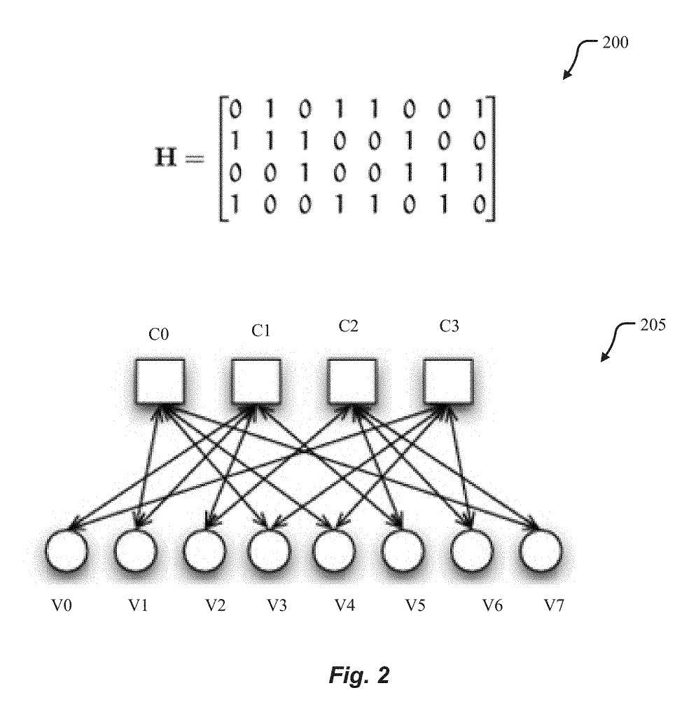

LDPC decoding circuit 140 may include hardware and/or software for decoding and error correcting the encoded read data 137 to output final read data 143 to the host controller circuit 105. The LDPC decoding circuit 140 and its operation according to example embodiments are discussed in more detail below with reference to FIGS. 2-9.

Although FIG. 1 illustrates LDPC encoding/decoding circuits 115/140 in the context of a storage system, it should be understood that example embodiments may also apply to a communications system for wired data transfer (e.g., using via fiber optic cables, copper wires, etc.) and/or wireless data transfer (e.g., using Wi-Fi, Long-Term Evolution (LTE), etc.). In this case, the LDPC encoding circuit 115 may be included at a transmitter side of the communications system for encoding data to be sent over a wired and/or wireless communications channel while the LDPC decoding circuit 140 may be included at a receiver side of the communications system for decoding the encoded data sent over the wired and/or wireless communications channel.

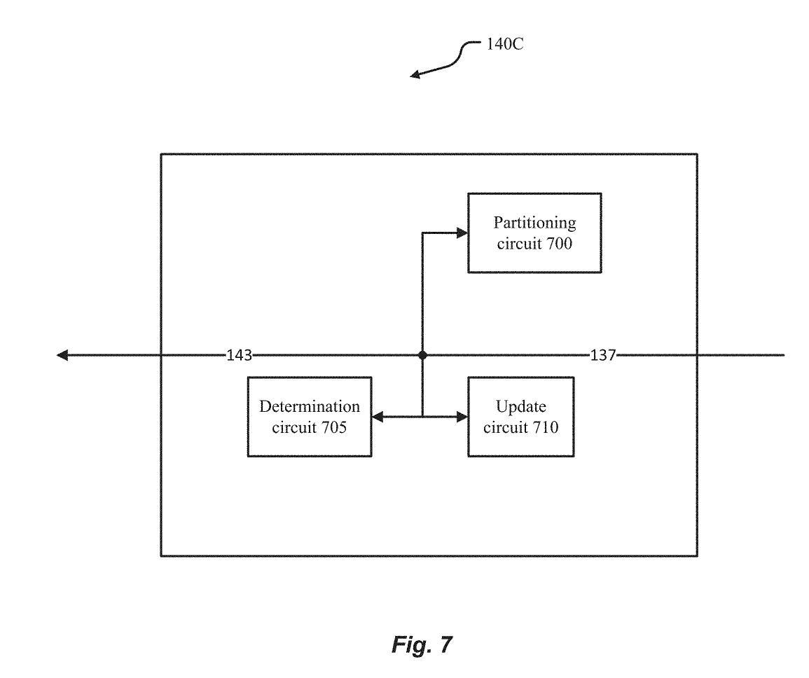

FIG. 2 illustrates an example LDPC code in the form of a parity matrix (or parity check matrix) H 200 and associated Tanner graph 205 for use in the system 100. As shown, the parity matrix H 200 is represented in the Tanner graph 205 by check nodes (CNs) C0-C3 and variable nodes (VNs) V0-V7. Each check node C0-C3 represents a row in the parity matrix H 200, and each variable node represents a column in the parity matrix H 200. FIG. 2 illustrates an example of a regular LDPC code where each column has a same weight, (i.e., the same number of is in each column of the parity matrix H 200). However, example embodiments may also apply to the use of irregular LDPC codes (see, e.g., FIGS. 7-9) where the columns have different weights (i.e., one or more columns have a different number of 1s from the other columns). The check nodes C0-C3 represent parity check equations used for encoding the original data to form a codeword (e.g., where the equations are modulo sums of code symbols) and each variable node V0-V7 represents a bit in the codeword (i.e., where a number of variable nodes is the number of bits in a codeword). In FIG. 2, there are four parity equations used to encode the data to form a codeword, and eight bits in the codeword. For decoding the codeword, messages pass back and forth between the check nodes and the variable nodes, and each message may include a probability (e.g., log likelihood ratio (LLR) in belief-propagation algorithms) that predicts the accuracy of each bit in the codeword. A message from a check node to a variable node is referred herein to as a check-to-variable (C2V) message, and a message from a variable node to a check node is referred herein to as a variable-to-check (V2C) message.

Here, it should be understood that example embodiments are not limited to the example LDPC code shown in FIG. 2, and that size of the LDPC code (i.e., the size of the parity check matrix H) may vary according to design preferences.

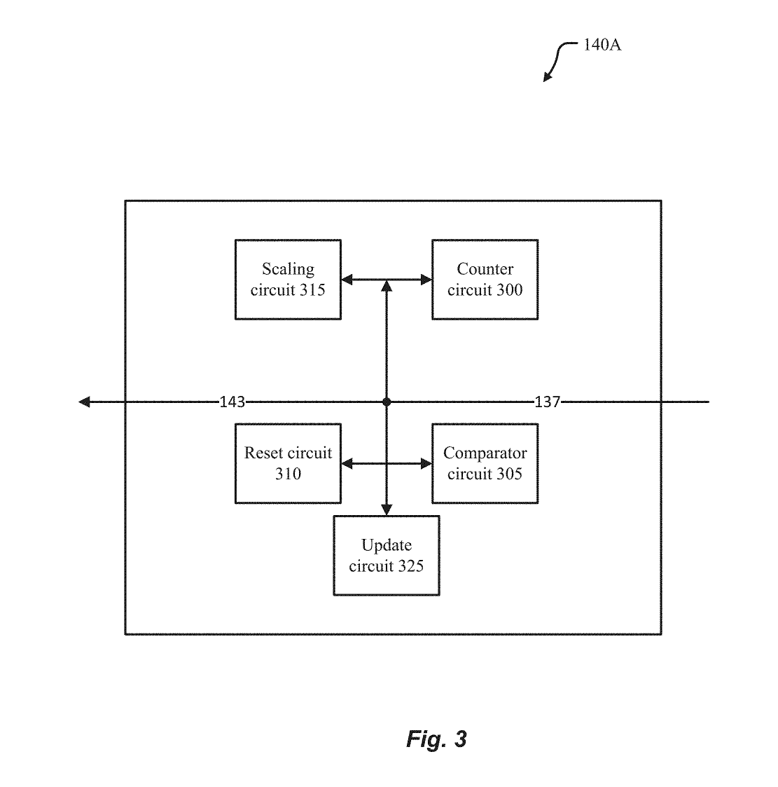

FIG. 3 illustrates a decoding circuit 140A according to at least one example embodiment.

As shown in FIG. 3, the decoding circuit 140A may include a counter circuit 300, a comparator circuit 305, a reset circuit 310, a scaling circuit 315, and an update circuit 325 in electrical communication with another via a suitable communications bus. Here, it should be understood that the decoding circuit 140A may include additional elements not illustrated for the sake of ease of explanation, but desired for properly decoding the encoded read data 137. FIG. 3 will be discussed with reference to elements from FIGS. 1 and 2.

The counter circuit 300 may include hardware and/or software for counting a number of violated checks that occur during a decoding process between a first time and a second time.

The comparator circuit 305 may include hardware (e.g., a comparator) and/or software for comparing the counted number of violated checks with a predetermined upper threshold and determining whether or not the counted number of violated checks meets or exceeds the predetermined upper threshold. In other words, the comparator circuit 305 may determine whether a particular check node C0-C3 is an unsatisfied check node (a check node is unsatisfied if a modulo sum associated with the check node is equal to 1). According to at least one example embodiment, the predetermined upper threshold is a design parameter set based on empirical evidence and/or preference, and represents a significant increase in the number of violated checks from a small number to a large number that occur between the first time and the second time.

The reset circuit 310 may include hardware and/or software for resetting check-to-variable messages in a parity check matrix in response to the comparator circuit 305 determining that the counted number of violated checks meets or exceeds the predetermined upper threshold. For example, the reset circuit 310 resets all of the check-to-variable messages in the parity check matrix in response to the comparator circuit 305 determining that the counted number of checks is violated.

The scaling circuit 315 may include hardware and/or software for generating scaling values based on the output of the comparator circuit 305, and apply the generated scaling values to the desired messages. For example, if the comparator circuit 305 determines that the counted number of violated checks does not meet or exceed the predetermined upper threshold, the scaling circuit 315 applies a first special scaling value to incoming variable-to-check messages for the unsatisfied check nodes, a second special scaling value to total log-likelihood ratio messages for the variable nodes connecting to the unsatisfied check nodes, and a third special scaling value to check-to-variable messages for the unsatisfied check nodes, and a regular scaling value to check-to-variable messages for the satisfied check nodes. According to at least one example embodiment, the first special scaling value is less than 1, the second special scaling value is the reciprocal of the first scaling value, and the third special scaling value is a relatively large value. Further, the first, second, and third special scaling values may be design parameters set based on empirical evidence and/or user preference. Otherwise, if the comparator circuit 305 determines that the counted number of violated checks does meet or exceed the predetermined upper threshold, the scaling circuit 315 applies the regular scaling value to check-to-variable messages for all the check nodes.

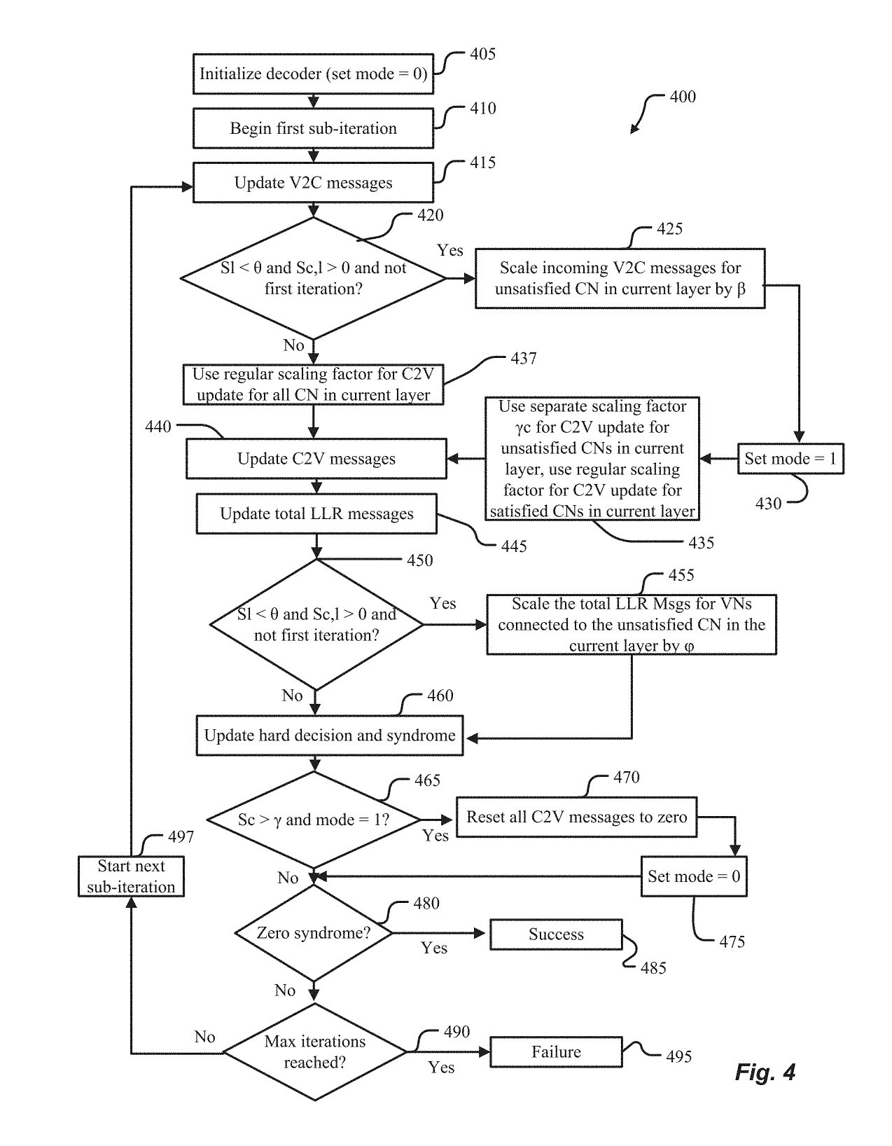

FIG. 4 illustrates an example method 400 for the decoding circuit 140A in FIG. 3. While a general order for the steps of the method 400 is shown in FIG. 4, the method 400 can include more or fewer steps or can arrange the order of the steps differently than those shown in FIG. 4. Generally, the method 400 starts at operation 405 and ends at operation 495. The method 400 can be executed as a set of computer-executable instructions executed by a computer system and encoded or stored on a computer readable medium. Alternatively, the operations discussed with respect to FIG. 4 may be implemented by the various elements of the system 100 (e.g., elements of the decoding circuit 140A) described with respect to FIGS. 1-3. Hereinafter, FIG. 4 shall be explained with reference to the systems, components, assemblies, devices, user interfaces, environments, software, etc. described in conjunction with FIGS. 1-3.

In operation 405, the method 400 initializes the decoding circuit 140A, which may include setting a binary mode flag to zero. The binary mode flag indicates whether the decoding circuit 140A is in a normal mode or a special scaling mode. Operation 400 may also include partitioning the parity matrix H into layers such that each layer has a column weight that is not greater than 1. For example, each layer in the parity matrix H 200 of FIG. 2 may correspond one of the rows in the parity matrix H 200. In some embodiments, the parity check nodes is partitioned into layers such that V2C and C2V message processing in a layer is completed before processing V2C and C2V messages in the next layer. Layer processing in this example is simplified if no variable node is connected to more than one check node in each layer. Operation 400 may also include initializing the total log-likelihood ratio for each variable node and setting all the C2V messages to zero.

In operation 410, the method 400 begins a first sub-iteration of a decoding process for decoding encoded data 137. Each sub-iteration may be carried out for one of the aforementioned layers and include a series of operations for a respective layer. Each iteration may consist of the consecutive sub-iterations for all of the layers in the parity matrix H.

In operation 415, the method 400 updates V2C messages for the parity matrix H. For example, the V2C message from variable node i to check node j is updated by summing the input and most recent C2V messages arriving at variable node i excluding the C2V message previously sent from check node j. The resulting summation is scaled and becomes the V2C message sent to check node j. Alternatively or additionally, the V2C messages can be updated by subtracting the old C2V message from the total log-likelihood ratio.

In operation 420, the method 400 determines i) whether Sl (a syndrome weight for the current layer in a previous iteration) is greater than a desired small number θ (e.g., 5 or 10), ii) whether Sc,l (a current syndrome weight for layer in the current iteration) is greater than zero, and iii) whether the method 400 is on the first sub-iteration. If all of conditions i), ii), and iii) are satisfied, the method 400 proceeds to operation 425. If not, the method 400 proceeds to operation 420. As can be appreciated by those of skill in the art, the syndrome weight may correspond to is the total number of unsatisfied parity checks.

In operation 425, the method 400 scales incoming V2C messages for the unsatisfied check node in the current layer by a first special scaling value β (e.g., a value less than 1).

In operation 430, the method 400 sets the mode flag to 1 to indicate that the method 400 has entered a mode in which the V2C and C2V and total LLR messages receive special scaling.

In operation 435, the method 400 determines to use a second special scaling value γ_{c} for the unsatisfied check nodes in the current layer for the upcoming operation 440, and still use the regular scaling value α for all the satisfied check nodes in the current layer for the upcoming operation 440. The second special scaling value γ_{c} is usually different from the first special scaling value β and from the regular scaling value γ.

Referring back to operation 420, if the query of this operation is answered negatively, then the method 400 continues by using a regular scaling value γ for all check nodes in the current layer for the upcoming operation (operation 437).

In operation 440, the method 400 may update the C2V messages for all the check node in the current layer using pre-determined scaling value from either operation 435 or operation 437, depending on the value of the mode flag. For example, the C2V messages are updated by min-sum algorithm with detail as follows:

$${L}_{i \to j} ← \{ {\prod }_{{j}^{′} ϵ M ( i ) \backslash j}^{ } sign ( {L}_{{j}^{′} \to i} ) \} \cdot {min}_{{j}^{′} ϵ M ( i ) \backslash j} \vert {L}_{{j}^{′} \to i} \vert , \\ where M ( i ) = \{ t : {h}_{i , t} \neq 0 \}$$

If not in the first iteration, and check node i is currently unsatisfied and Sₗ<θ, L_{i→j}→γ_{c}·L_{i→j}; Otherwise, L_{i→j}→α·L_{i→j}

The updated C2V message from check node j to variable node i may be computed using the most recent V2C messages arriving at check node j excluding the V2C message previously sent from variable node i. In an example embodiment based on the min-sum algorithm, the magnitude of the C2V message is the minimum magnitude of the V2C messages, appropriately scaled. The sign of the V2C message is positive if an odd number of C2V messages are positive and negative otherwise.

In operation 445, the method 400 updates the total LLR messages. For example, the total LLR for variable node i is computed by summing the input and all the most recent C2V messages arriving at variable node i.

In operation 450, the method 400 determines whether i) whether Sₗ (the total number of unsatisfied check nodes in the end of a previous iteration) is less than the desired small number θ (e.g., 10), ii) whether S_{c,l} (the number of unsatisfied check nodes in the current layer for the current iteration) is greater than zero, and iii) whether the method 400 is on the first iteration. If all of conditions i), ii), and iii) are satisfied, the method proceeds to operation 455. If not, the method 400 proceeds to operation 460.

In operation 455, the method 400 scales the total LLR messages for variable nodes connected to the unsatisfied check nodes in the current layer by a third scaling value φ. According to at least one example embodiment, φ·β=1.

In operation 460, the method 400 includes updating a hard decision and syndrome weight. For example, the method 400 updates the hard decision for each variable node according to the following: hard decision=1 if total LLR<0; hard decision=0 if total LLR≥0.

In operation 465, the method 400 includes determining whether i) Sc (the current syndrome weight for the entire parity matrix H) is greater than a predetermined relatively large number (e.g., 200, 300, 500, or 1000), and ii) whether the mode flag is set to 1. If so, the method proceeds to operation 470. If not, the method 400 proceeds to operation 480.

In operation 470, the method 400 includes resetting all C2V messages to zero.

In operation 475, the method 400 includes setting the mode flag to zero.

In operation 480, the method 400 determines whether the current syndrome weight is zero. If so, the method 400 proceeds to operation 485 and determines the decoding process to be a success (i.e., the codeword has been successfully decoded). If not, the method 400 proceeds to operation 490.

In operation 490, the method 400 determines whether a desired number of maximum iterations has been reached. If so, the method 400 proceeds to operation 495 and determines the decoding process to be a failure. If not, the method proceeds to operation 497 to start the next sub-iteration for the next layer.

In view of FIGS. 1-4, it should be appreciated that example embodiments include partitioning the parity-check matrix H=[h_{i,j}] into layers, where the column weight for each layer is at most 1. For the sake of explanation, let L_{j,in} and Lⱼ be the decoder input and output for VN j, respectively. Let Sₗ denote the syndrome weight in the last iteration and S_{c} be the current syndrome weight. Let I be the iteration index starting from 0. In addition, let “mode” be a binary flag to indicate the decoder mode. With the above in mind, example embodiments include the following:
Initialization: Set Lⱼ=L_{j,in} for all the VN j, all the c2vMsgs L_{i→j} are initialized to 0, set mode=0.
For each iteration, the following updates are applied to each layer sequentially from the top to the bottom layer:
VN-to-CN (V2C) update from VN j to check node (CN) i: L_{j→i}←Lⱼ−L_{i→j}
If I>0, and check node i is currently unsatisfied and Sₗ<θ, L_{j→i}←β·L_{j→i} and mode=1
CN-to-VN (C2V) update from CN i to VN j:

$${L}_{i \to j} ← \{ {\prod }_{{j}^{′} ϵ M ( i ) \backslash j}^{ } sign ( {L}_{{j}^{′} \to i} ) \} \cdot {min}_{{j}^{′} ϵ M ( i ) \backslash j} \vert {L}_{{j}^{′} \to i} \vert ,$$

where M(i)={t: h_{i,t}≠0}
If I>0, and check node i is currently unsatisfied and Sₗ<θ, L_{i→j}→λ_{c}·L_{i→j}; Otherwise, L_{i→j}→λ·L_{i→j}
Total LLR update for VN j: Lⱼ←L_{j→i}+L_{i→j}
If I>0, and check node i is currently unsatisfied and Sₗ<θ, Lⱼ←ϕ·Lⱼ
Hard Decision (HD) and syndrome update
If S_{c}>a predetermined threshold and mode=1, all the c2vMsgs L_{i→j} are reset to 0 and set mode=0.

In view of FIGS. 1-4, it should be understood that separate scaling is applied only to messages associated with unsatisfied check nodes, and that resets C2V messages to zero if certain conditions are met. As a result of the circuits and operations describe with reference to FIGS. 1-4, the error floor of a fixed point LDPC decoding circuit 140A may be lowered, and thus decoding performance improved. For example, the error floor may be lowered by roughly a factor of 100 compared to related art solutions.

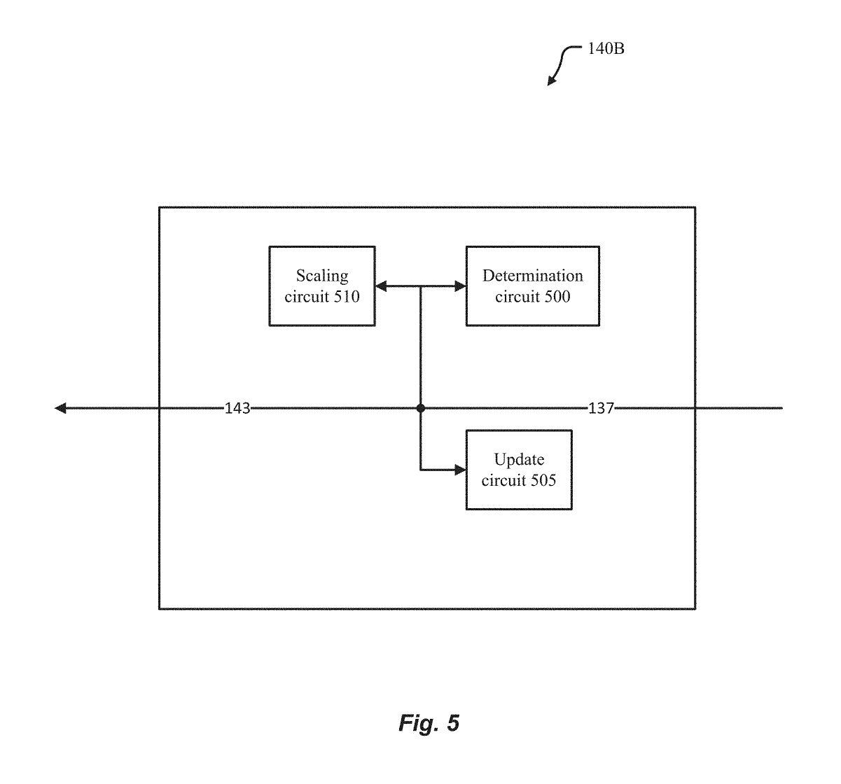

FIG. 5 illustrates a decoding circuit 140B according to at least one example embodiment.

As shown in FIG. 5, the decoding circuit 140B includes a determination circuit 500, a scaling circuit 505, and an update circuit 510. Here, it should be understood that the decoding circuit 140B may include additional elements not illustrated for the sake of ease of explanation, but desired for properly decoding the encoded read data 137. FIG. 5 will be discussed with reference to elements from FIGS. 1 and 2.

The determination circuit 500 may determine, for a particular check node, whether two minimums of the absolute values of incoming variable-to-check messages are close to one another. For example, if a particular check node receives four incoming variable-to-check messages, the two messages having the smallest absolute value are used for determining the absolute values of the two minimums.

According to at least one example embodiment, the determination circuit 500 comprises a comparator circuit that determines a difference between a first minimum and a second minimum by applying a subtraction operation. In this case, the determination circuit 500 compares the difference between the first absolute value and the second absolute value with a second positive predetermined threshold to determine whether or not the two minimums of the absolute values of the incoming variable-to-check messages are close to one another. The second positive predetermined threshold may be a design parameter set based on empirical evidence and/or preference.

The scaling circuit 510 applies either a first scaling value or a second scaling value to check-to-variable messages for the particular check node depending upon whether the determination circuit 500 determines that two minimums of the absolute values of the incoming variable-to-check messages are close to one another. For example, the scaling circuit 510 applies the first scaling value when the two minimums are close to one another, and applies the second scaling value when the two minimums are not close to one another. Here, the first scaling value is distinct from the second scaling value. For example, the first scaling value may be less than the second scaling value because if the two minimums are close to one another, then there is a smaller scale factor. Further, the first and second scaling values may be design parameters set based on empirical evidence and/or preference.

The update circuit 505 computes the check-to-variable messages prior to the second circuit applying the first scaling value or the second scaling value. For example, the update circuit 505 computes the check-to-variable messages using a min-sum algorithm.

In view of the above, it should be appreciated that the circuits 500, 505, and 510 continuously process a stream of incoming data that results in the particular check node and a plurality of other check nodes.

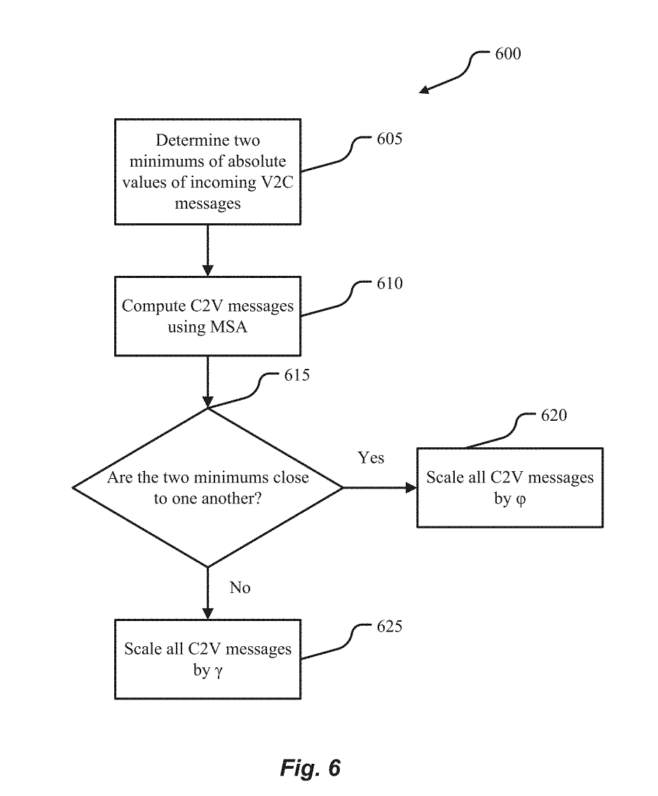

FIG. 6 illustrates a method 600 for the decoding circuit 140B of FIG. 5.

While a general order for the steps of the method is shown in FIG. 6, the method 600 can include more or fewer steps or can arrange the order of the steps differently than those shown in FIG. 6. Generally, the method 600 starts at operation 605 and ends at operation 625. The method 600 can be executed as a set of computer-executable instructions executed by a computer system and encoded or stored on a computer readable medium. Alternatively, the operations discussed with respect to FIG. 6 may be implemented by the various elements of the system 100 (e.g., elements of the decoding circuit 140B) discussed with reference to FIGS. 1, 2, and 5. Hereinafter, FIG. 6 shall be explained with reference to the systems, components, assemblies, devices, user interfaces, environments, software, etc. described in conjunction with FIGS. 1, 2, and 5.

In operation 605, the method 600 includes determining, for a particular check node, two minimums of incoming V2C messages. For example, operation 605 determines the two minimums of the absolute values of incoming V2C messages.

In operation 610, the method 600 includes computing C2V messages. For example, the C2V messages are computed using a min-sum algorithm.

In operation 615, the method 600 includes determining whether the two minimums are statistically close to one another. For example, operation 615 determines whether the two minimums of the absolute values are close to one another. In at least one example embodiment, this determination is made by dividing a first minimum of the two minimums by a second minimum of the two minimums to determine a ratio between the first minimum of absolute values and the second minimum of absolute values, and comparing the ratio between the first minimum of absolute values and the second minimum of absolute values with a first threshold to determine whether or not the two minimums of the absolute values of the incoming variable-to-check messages are close to one another. In at least one example embodiment, the determination is made by computing a difference between the first minimum of absolute values and the second minimum of absolute values and comparing the difference with a second threshold to determine whether or not the two minimums of the absolute values are close to one another. As shown, computing the check-to-variable messages may occur prior to applying the first scaling value or the second scaling value in operations 620 and 625. As with the first and second scaling values, the first and second thresholds may be design parameters set based on empirical evidence and/or preference.

In operations 620 and 625, the method 600 includes applying either a first scaling value φ or a second scaling value γ to check-to-variable messages for the particular check node depending upon whether the two minimums are close to one another.

For example, if, in operation 615, the method 600 determines that the two minimums (or the two minimums of absolute values) are close to one another, then the method proceeds to operation 620 to apply the first scaling value φ. If in operation 615, the method 600 determines that the two minimums (or the two minimums of absolute values) are not close to one another, then the method proceeds to operation 625 to apply the second scaling value γ. According to at least one example embodiment, the first scaling value φ is applied if the absolute values of the two minimums are close to one another (e.g., within a predetermined distance from one another), and the second scaling value when the absolute values of the two minimums are not close to one another.

In view of FIGS. 1, 2, 5, and 6, it should be appreciated that example embodiments may improve the error correction performance of a min-sum LDPC decoder (e.g., circuit 140B). For the sake of explanation, let H=[h_{i,j}] be the parity-check matrix of the LDPC codes. Then:
For CN i, let M(i)={t: h_{i,t}≠0} be all the VNs connecting to the CN i
For CN i and VN j, let L_{i→j} and L_{j→i} denote the messages sent from i to j, and from j to i, respectively.
Let min1,min2 be the 1^{st} and 2^{nd} minimum of a (|L_{t→i}|)_{t∈M(i)} (min1,min2 can be equal), let P=Π_{t∈M(i)}sign(L_{t→i})
Let min1Loc=argmin_{j∈M(i)}|L_{j→i}| (only pick single argument if there is more than 1 minimum)

C2V Update from CN i to VN j:
Step 1:

$${L}_{i \to j} ← {\prod }_{{j}^{′} ϵ M ( i ) \backslash j}^{ } sign ( {L}_{{j}^{′} \to i} ) \cdot {min}_{{j}^{′} ϵ M ( i ) \backslash j} \vert {L}_{{j}^{′} \to i} \vert = \{ \begin{matrix}P \cdot sign ( {L}_{j \to i} ) \cdot min 2 , j = min 1 Loc \\ P \cdot sign ( {L}_{j \to i} ) \cdot min 1 , otherwise\end{matrix}$$

Step 2: Dynamic scaling based on the relationship between min1 and min2:

$$If \frac{min 1}{min 2} > γ$$

$$set {L}_{i \to j} ← φ \cdot {L}_{i \to j} ;$$

$$Else$$

$$set {L}_{i \to j} ← λ \cdot {L}_{i \to j} .$$

FIG. 7 illustrates a decoding circuit 140C according to at least one example embodiment. As shown in FIG. 7, the decoding circuit 140C includes a partitioning circuit 700, a determination circuit 705, an update circuit 710. Here, it should be understood that the decoding circuit 140C may include additional elements not illustrated for the sake of ease of explanation, but desired for properly decoding the encoded read data 137. FIG. 7 will be discussed with reference to elements from FIGS. 1 and 2.

Decoding circuit 140C may be applied to implementations that use irregular LDPC codes, where at least one of the columns in the parity matrix H has a column weight that differs from the other columns.

The partitioning circuit 700 may include hardware and/or software for partitioning the variable nodes V0-V7 (of a data codeword or decoding data) into different subsets based on their degrees (or column weights). For example, the partitioning circuit 700 partitions the variable nodes with lower degrees into a first subset, and partitions the variable nodes with higher degrees into a second subset that is distinct from the first subset. For example, if the parity matrix H includes four columns with a column weight of one and four columns with a column weight two, then the columns having a weight of one are partitioned into a first group and the columns having a weight of two are partitioned into a second group. However, example embodiments are not limited thereto, and the parity matrix H may be partitioned into any number of groups, where each group has columns of a same column weight or columns with different column weights depending upon design preferences.

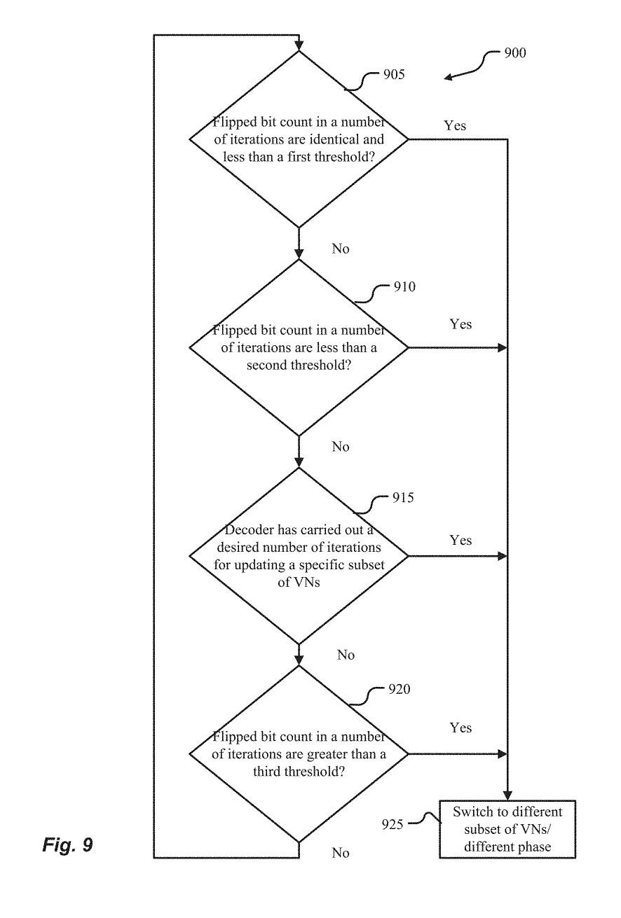

The determination circuit 705 may include hardware and/or software for determining whether a switching condition has occurred in connection with bit-flipping the decoding data of the irregular LDPC codes. For example, the determination circuit 705 switches from the first subset of variable nodes to the second subset of variable nodes in response to determining that the switching condition has occurred, or switch from one phase to the other phase. FIG. 9 illustrates a number of possible switching conditions in more detail.

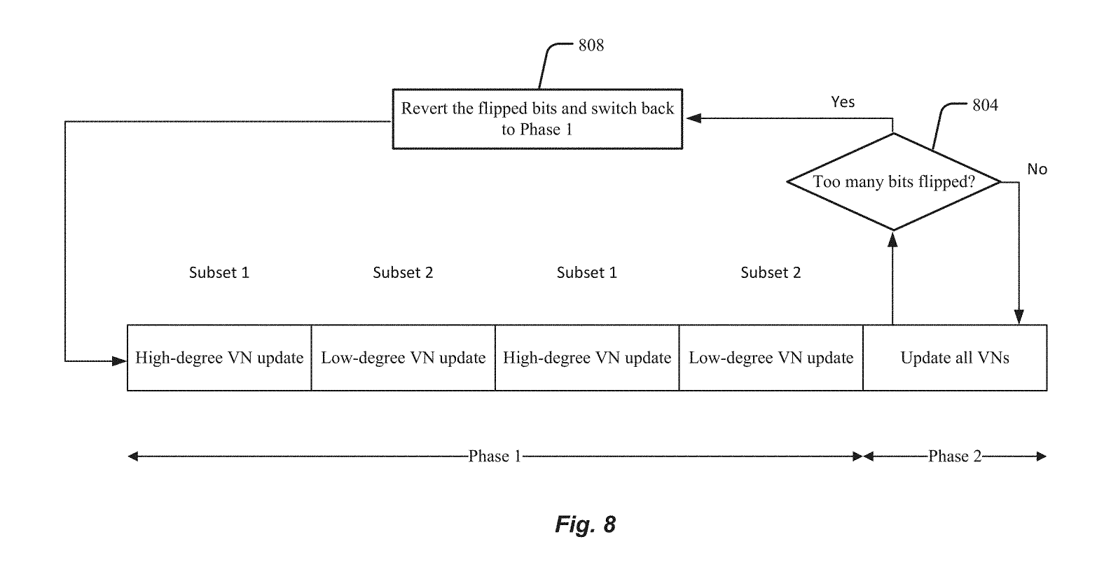

The update circuit 710 may include hardware and/or software for processing the different subsets in a first phase and second phase. For example, in the first phase, the update circuit 710 alternately updates subsets with a high degree and subsets with a low degree. In the second phase, the update circuit 710 updates the variable nodes in all of the different subsets. For example, the update circuit 710 is configured to apply an update rule where every variable node connected to more than T (e.g., a predetermined value) unsatisfied checks is flipped. According to at least one example embodiment, the update circuit 710 applies a different variable node update algorithm to each subset of variable nodes. For example, the update circuit 710 applies a first variable node update algorithm to the first subset of variable nodes compared to the second subset of variable nodes. Examples of update algorithms include min-sum algorithms, sum-product algorithms, majority vote, various types of bit-flipping algorithms, etc. FIG. 8 illustrates the first and second phases in more detail.

FIG. 8 illustrates first and second phases of updating subsets of variable nodes in according to at least one example embodiment.

During the second phase, the decoder can switch back to the first phase if a switching condition is met. As a non-limiting example, if the number of flipped bits in an iteration exceeds a relatively large threshold as determined in operation 804, the decoder reverts the flipped bits and switches back from the second phase to the first phase in operation 808. If the condition of operation 804 is not met, then the decoder continues with the second phase.

For the sake of explanation, assume that a given set of variable nodes has been partitioned into Subset 1 having high degree variable nodes and Subset 2 having low degree variable nodes. As shown in FIG. 8, the first phase includes updating only Subset 1 for a consecutive number of iterations, followed by updating only Subset 2 for a consecutive number of iterations. Then, Subset 1 is again updated for a consecutive number of iterations, and Subset 2 is again updated for a consecutive number of iterations. As shown, multiple iterations are carried out in the first phase so that most errors have been corrected. Then, a second phase begins in which all variable nodes in all subsets are updated. As noted above, switching from one subset to a next subset, or from one phase to the other phase, may depend upon whether one or more switching conditions are met, illustrated in more detail by FIG. 9.

FIG. 9 illustrates a method 900 for switching conditions of the decoding circuit 140C of FIG. 7 according to at least one example embodiment.

While a general order for the steps of the method is shown in FIG. 9, the method 900 can include more or fewer steps or can arrange the order of the steps differently than those shown in FIG. 9. Generally, the method 900 starts at operation 905 and ends at operation 925. The method 900 can be executed as a set of computer-executable instructions executed by a computer system and encoded or stored on a computer readable medium. Alternatively, the operations discussed with respect to FIG. 9 may be implemented by the various elements of the system 100 (e.g., elements of the decoding circuit 140C) discussed with reference to FIGS. 1, 2, 7, and 8. Hereinafter, FIG. 9 shall be explained with reference to the systems, components, assemblies, devices, user interfaces, environments, software, etc. described in conjunction with FIGS. 1, 2, 7, and 8.

In operation 905, the method 900 determines whether a flipped bit count in a number of iterations are identical and less than a first threshold. If so, the method 900 proceeds to operation 925 to switch to a different subset of variable nodes or switch to a different phase. If not, the method 900 proceeds to operation 910. Here, the first threshold may be a design parameter set based on empirical evidence and/or preference.

In operation 910, the method 900 determines whether a flipped bit count in a number of iterations are less than a second threshold. If so, the method 900 proceeds to operation 925. If not, the method 900 proceeds to operation 915. Here, the second threshold may be a design parameter set based on empirical evidence and/or preference.

In operation 915, the method 900 determines whether the decoding circuit 140C has carried out a desired number of iterations for updating a specific subset of variable nodes. If so, the method 900 proceeds to operation 925. If not, the method 900 proceeds to operation 920. Here, the desired number of iterations may be a design parameter set based on empirical evidence and/or preference.

In operation 920, the method 900 determines whether a flipped bit count in a desired number of iterations is greater than a third threshold. If so, the method 900 proceeds to operation 925. If not, the method 900 returns to operation 905. Here, the desired number of iterations and the third threshold may be design parameters set based on empirical evidence and/or user preference.

In view of FIG. 9, it should be understood that the decoding circuit 140C may switch between subsets of VNs or different phases if any one, a combination of at least two, or all of the following conditions are met: i) the flipped bit counts in a predetermined number of consecutive iterations are identical and small, ii) the flipped bit counts in a predetermined number of consecutive iterations are all less than a predetermined small threshold, iii) the flipped bit counts in a predetermined number of consecutive iterations are all larger than a predetermined small threshold, iv) the decoder has carried out a predetermined number of consecutive iterations for updating a specific subset of VNs only, v) the flipped bit counts in a iteration are larger than a predetermined large threshold.

In view of FIGS. 1, 2, and 7-9, it should be appreciated that example embodiments relate to a two-phase decoding method that can improve the performance for bit-flipping decoding of irregular LDPC codes. Here, the VNs are partitioned into different subsets based on their degrees. In phase I, only one subset of variable nodes (VNs) is updated in each iteration, and other subsets of VNs are frozen. In phase 1, example embodiments can switch from one subset to another subset if some specific switching conditions are met. Additionally, different VN update algorithms may be applied to different subsets. In phase 2, all VNs are updated in each iteration. Example embodiments can also switch between phase 1 and phase 2 if some specific switching conditions are met.

It should be understood that decoding circuits and/or decoding methods according to example embodiments have been described with details that relate to improvements over existing decoders/methods. In other words, the above described decoding circuits and/or methods may include additional hardware/software and/or operations not described herein but known in the art to be desired for LDPC decoding.

It should be understood that example embodiments are directed to systems that include decoding circuits for improving decoding performance by at least one of lowering an error floor, reducing bit error rates (BERs), and improving signal to noise ratios (SNR).

At least one example embodiment is directed to a Low-Density Parity-Check (LDPC) decoder including a first circuit configured to, for a particular check node, determine whether two minimums of the absolute values of incoming variable-to-check messages are statistically close to one another. The LDPC decoder includes a second circuit configured to apply either a first scaling value or a second scaling value to check-to-variable messages for the particular check node depending upon whether the first circuit determines that the absolute values of the two minimums of the absolute values of incoming variable-to-check messages are close to one another.

According to at least one example embodiment, the first circuit divides a first absolute value of a first minimum of the two minimums by a second absolute value of a second minimum of the two minimums to determine a ratio between the first absolute value and the second absolute value.

According to at least one example embodiment, the first circuit compares the ratio between the first absolute value and the second absolute value with a positive predetermined threshold to determine whether or not the absolute values of the incoming variable-to-check messages are statistically close to one another.

According to at least one example embodiment, the first scaling value is distinct from the second scaling value.

According to at least one example embodiment, the first circuit comprises a comparator circuit that determines a difference between a first minimum and a second minimum by applying a subtraction operation.

According to at least one example embodiment, the first circuit compares the difference between the first minimum of absolute values and the second minimum of absolute values with a positive predetermined threshold to determine whether or not the two minimums of the absolute values of the incoming variable-to-check messages are close to one another.

According to at least one example embodiment, the first circuit and second circuit continuously process a stream of incoming data that results in the particular check node and a plurality of other check nodes.

According to at least one example embodiment, the first scaling value is less than the second scaling value.

According to at least one example embodiment, the second circuit applies the first scaling value when the absolute values of the two minimums are close to one another, and the second circuit applies the second scaling value when the two minimums of the absolute values are not close to one another.

According to at least one example embodiment, the LDPC decoder includes a third circuit configured to compute the check-to-variable messages prior to the second circuit applying the first scaling value or the second scaling value.

According to at least one example embodiment, the third circuit is configured to compute the check-to-variable messages using a min-sum algorithm.

At least one example embodiment is directed to a method that includes determining, for a particular check node, two minimums of absolute values of incoming variable-to-check messages, and applying either a first scaling value or a second scaling value to check-to-variable messages for the particular check node depending upon whether the two minimums are close to one another.

According to at least one example embodiment, the method further comprises determining absolute values of the two minimums of absolute values of the incoming variable-to-check messages, and the applying applies either the first scaling value or the second scaling value based on whether the two minimums of absolute values are close to one another.

According to at least one example embodiment, the method further comprises dividing a first minimum of the two minimums by a second minimum of the two minimums to determine a ratio between the first minimum of absolute values and the second minimum of absolute values.

According to at least one example embodiment, the method further comprises comparing the ratio between the first minimum of absolute values and the second minimum of absolute values with a threshold to determine whether or not the two minimums of the absolute values of the incoming variable-to-check messages are close to one another.

According to at least one example embodiment, the first scaling value is less than the second scaling value.

According to at least one example embodiment, the applying applies the first scaling value if the two minimums of the absolute values are close to one another, and the applying applies the second scaling value when the two minimums of the absolute values are not close to one another.

According to at least one example embodiment, the method further comprises computing the check-to-variable messages prior to applying the first scaling value or the second scaling value.

According to at least one example embodiment, the computing computes the check-to-variable messages using a min-sum algorithm.

At least one example embodiment is directed to a Parity-Check (LDPC) decoder including a first circuit configured to partition variable nodes of a data codeword into different subsets based degrees of the variable nodes, a second circuit configured to determine whether a switching condition has occurred in connection with bit-flipping in the data codeword of irregular LDPC codes, and a third circuit configured to process the different subsets in a first phase and second phase according to the following: i) in the first phase, alternately updating subsets with a high degree and subsets with a low degree; and ii) in the second phase, updating the variable nodes in all of the different subsets.

According to at least one example embodiment, the second circuit is further configured to switch from the first subset of variable nodes to the second subset of variable nodes in response to the first circuit determining that the switching condition has occurred, or to switch from one phase to the other phase in response to the first circuit determining that the switching condition has occurred.

According to at least one example embodiment, a different variable node update algorithm is applied to the first subset of variable nodes as compared to the second subset of variable nodes.

According to at least one example embodiment, the second circuit determines whether the switching condition has occurred by counting a number of flipped bits in a predetermined number of consecutive iterations and comparing the counted number of flipped bits to a predetermined threshold.

According to at least one example embodiment, the second circuit determines whether the switching condition has occurred by counting a number of consecutive iterations for updating a specific subset of variable nodes.

According to at least one example embodiment, the variable nodes are partitioned into the different subsets based on degrees.

According to at least one example embodiment, the third circuit applies a plurality of iterations in the first phase.

At least one example embodiment is directed to a Low Density Parity-Check (LDPC) decoder including a first circuit configured to count a number of violated checks that occur during a decoding process between a first time and a second time, a second circuit configured to compare the counted number of violated checks with a predetermined upper threshold and determine whether or not the counted number of violated checks meets or exceeds the predetermined upper threshold, and a third circuit configured to reset check-to-variable messages in a parity check matrix in response to the second circuit determining that the counted number of violated checks meets or exceeds the predetermined upper threshold.

According to at least one example embodiment, the third circuit resets all of the check-to-variable messages in the parity check matrix in response to the second circuit determining that the counted number of violated.

According to at least one example embodiment, the LDPC decoder includes a fourth circuit configured to apply separate scaling values to unsatisfied check nodes in response to the second circuit determining that the counted number of violated checks does not meet or exceed the predetermined upper threshold, and apply the regular scaling values to the satisfied check nodes.

According to at least one example embodiment, the fourth circuit applies: a first special scaling value to incoming variable-to-check messages for the unsatisfied check nodes, a second special scaling value to total log-likelihood ratio messages for the unsatisfied check nodes, a third special scaling value to check-to-variable messages for the unsatisfied check nodes, and a regular scaling value to the check-to-variable messages for the satisfied check nodes.

According to at least one example embodiment, the first special scaling value is less than 1, the second special scaling value is the reciprocal of the first special scaling value, and the third special scaling value is different from the first special scaling value and the second special scaling value and may correspond to a relatively large value.

According to at least one example embodiment, the predetermined upper threshold represents a significant increase in the number of violated checks from a small number to a large number that occur between the first time and the second time.

At least one example embodiment is directed to an optical communication system comprising at least one of the above LDPC decoders.

At least one example embodiment is directed to a memory controller including at least one of the above LDPC decoders.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

Aspects of the present disclosure may take the form of an embodiment that is entirely hardware, an embodiment that is entirely software (including firmware, resident software, micro-code, etc.) or an embodiment combining software and hardware aspects that may all generally be referred to herein as a “circuit,” “module,” or “system.” Any combination of one or more computer-readable medium(s) may be utilized. The computer-readable medium may be a computer-readable signal medium or a computer-readable storage medium.

A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device. Program code embodied on a computer-readable medium may be transmitted using any appropriate medium, including, but not limited to, wireless, wireline, optical fiber cable, RF, etc., or any suitable combination of the foregoing.

The terms “determine,” “calculate,” “compute,” and variations thereof, as used herein, are used interchangeably and include any type of methodology, process, mathematical operation or technique.

What is claimed is:

1. A Low-Density Parity-Check (LDPC) decoder, comprising:
a first circuit configured to, for a particular check node, determine whether two minimums of absolute values of incoming variable-to-check messages are close to one another; and
a second circuit configured to apply either a first scaling value or a second scaling value to check-to-variable messages for the particular check node depending upon whether the first circuit determines that the two minimums of the absolute values of the incoming variable-to-check messages are close to one another.

2. The LDPC decoder of claim 1, wherein the first circuit divides a first absolute value of a first minimum of the two minimums by a second absolute value of a second minimum of the two minimums to determine a ratio between the first absolute value and the second absolute value.

3. The LDPC decoder of claim 2, wherein the first circuit compares the ratio between the first absolute value and the second absolute value with a positive predetermined threshold to determine whether or not the absolute values of the incoming variable-to-check messages are statistically close to one another.

4. The LDPC decoder of claim 1, wherein the first scaling value is distinct from the second scaling value.

5. The LDPC decoder of claim 1, wherein the first circuit comprises a comparator circuit that determines a difference between a first minimum of absolute values and a second minimum of absolute values by applying a subtraction operation.

6. The LDPC decoder of claim 5, wherein the first circuit compares the difference between the first minimum of absolute values and the second minimum of absolute values with a positive predetermined threshold to determine whether or not the two minimums of the absolute values of the incoming variable-to-check messages are close to one another.

7. The LDPC decoder of claim 1, wherein the first circuit and second circuit continuously process a stream of incoming data that results in the particular check node and a plurality of other check nodes.

8. The LDPC decoder of claim 1, wherein the first scaling value is less than the second scaling value.

9. The LDPC decoder of claim 8, wherein the second circuit applies the first scaling value when the absolute values of the two minimums are close to one another, and wherein the second circuit applies the second scaling value when the two minimums of the absolute values are not close to one another.

10. The LDPC decoder of claim 1, further comprising:
a third circuit configured to compute the check-to-variable messages prior to the second circuit applying the first scaling value or the second scaling value.

11. The LDPC decoder of claim 10, wherein the third circuit is configured to compute the check-to-variable messages using a min-sum algorithm.

12. A method of operating an LDPC decoder, comprising:
determining, for a particular check node, two minimums of absolute values of incoming variable-to-check messages; and
applying either a first scaling value or a second scaling value to check-to-variable messages for the particular check node depending upon whether the two minimums are close to one another.

13. The method of claim 12, further comprising:
determining absolute values of the two minimums of the absolute values of the incoming variable-to-check messages, wherein the applying applies either the first scaling value or the second scaling value based on whether the two minimums of the absolute values are close to one another.

14. The method of claim 13, further comprising:
dividing a first minimum of the two minimums by a second minimum of the two minimums to determine a ratio between the first minimum of the absolute values and the second minimum of the second absolute values.

15. The method of claim 14, further comprising:
comparing the ratio between the first minimum of the absolute values and the second minimum of the absolute values with a threshold to determine whether or not the two minimums of the absolute values of the incoming variable-to-check messages are close to one another.

16. The method of claim 13, wherein the first scaling value is less than the second scaling value.

17. The method of claim 16, wherein the applying applies the first scaling value if the two minimums of the absolute values are close to one another, and wherein the applying applies the second scaling value when the two minimums of the absolute values are not close to one another.

18. The method of claim 13, further comprising:
computing the check-to-variable messages prior to applying the first scaling value or the second scaling value.

19. The LDPC decoder of claim 18, wherein the computing computes the check-to-variable messages using a min-sum algorithm.

20. A Low-Density Parity-Check (LDPC) decoder, comprising:
a first circuit configured to partition variable nodes of a data codeword into different subsets based degrees of the variable nodes; and
a second circuit configured to determine whether a switching condition has occurred in connection with bit-flipping in the data codeword of irregular LDPC codes; and
a third circuit configured to process the different subsets in a first phase and second phase according to the following:
in the first phase, alternately updating subsets with a high degree and subsets with a low degree; and
in the second phase, updating the variable nodes in all of the different subsets.
